(19) United States
(12) Patent Application Publication
(10) Pub. No.: US 2017/0004968 A1
(43) Pub. Date: Jan. 5, 2017

(54) SEMICONDUCTOR DEVICE

(71) Applicant: Applied Materials, Inc., Santa Clara, CA (US)

(72) Inventors: Xinyu BAO, Fremont, CA (US); Zhiyuan YE, San Jose, CA (US); Jean-Baptiste PIN, Grenoble (FR); Errol SANCHEZ, Tracy, CA (US); Franck BASSANI, Grenoble (FR); Thierry BARON, Grenoble (FR); Yann BOGUMILOWICZ, Grenoble (FR); Jean-Michel HARTMANN, Grenoble (FR)

(21) Appl. No.: 15/194,361

(22) Filed: Jun. 27, 2016

(30) Foreign Application Priority Data
Jul. 3, 2015 (FR) PCT/FR2015/051858

(51) Int. Cl. H01L 21/02; H01L 29/201; H01L 29/06; H01L 29/04

(52) U.S. Cl. CPC H01L 21/02433; H01L 29/045; H01L 29/201; H01L 29/0657; H01L 21/02381; H01L 21/02694; H01L 21/02549; H01L 21/02546; H01L 21/02543

(57) ABSTRACT

A semiconductor device is disclosed that has a semiconductor substrate having a crystal structure with a <1,0,0> plane and a <1,1,0> plane and a surface that forms an angle of about 0.3 degrees to about 0.7 degrees with the <1,0,0> plane in the direction of the <1,1,0> plane; and a compound semiconductor layer formed on the semiconductor substrate. The compound semiconductor layer is free of antiphase boundaries, and has a thickness between about 200 nm and about 1,000 nm.

### CROSS-REFERENCE TO RELATED APPLICATIONS

This application claims benefit, under 35 U.S.C. §120, of International Application No. PCT/FR2015/051858, filed in compliance with 35 U.S.C. §363 on Jul. 3, 2015, which is incorporated herein by reference.

### FIELD

Embodiments of the present disclosure generally relate to semiconductor devices and methods making semiconductor devices. More specifically, embodiments described herein relate to methods and apparatus for performing epitaxy with compound semiconductor materials.

### BACKGROUND

Epitaxy is a process that involves chemical addition of material to a surface in layers. Such processes are common in semiconductor processing, where they are used for building certain components of logic, memory and optoelectronic devices. In a typical process for making a logic device, a channel component of a transistor is epitaxially formed on a silicon substrate. Increasingly, the channel component is formed from materials that have a crystal structure different from that of silicon. Similar situations exist for other active device regions in logic, memory and optoelectronic device types. Among the materials of interest are compound semiconductors, such as III/V materials (combinations of materials from Group III and Group V of the periodic table). Apart from defects that arise due to lattice size mismatch with silicon, the polar nature of III/V materials can result in Anti-Phase Boundary (APB) defects when grown over the non-polar silicon substrate. To produce high quality layers of these materials, methods of forming low, or zero, defect III/V layers on a silicon substrate are needed.

### SUMMARY

Embodiments of the present disclosure provide a semiconductor device, comprising a semiconductor substrate having a crystal structure with a <1,0,0> plane and a <1,1,0> plane and a surface that forms an angle of about 0.3 degrees to about 0.7 degrees with the <1,0,0> plane in the direction of the <1,1,0> plane; and a compound semiconductor layer formed on the semiconductor substrate. The compound semiconductor layer is free of antiphase boundaries, and has a thickness between about 200 nm and about 1,000 nm.

Also disclosed is a method of forming a semiconductor device, comprising forming a surface on a semiconductor substrate having a crystal structure with a <1,0,0> plane and a <1,1,0> plane, the surface forming an angle of about 0.3 degrees to about 0.7 degrees with the <1,0,0> plane in the direction of the <1,1,0> plane; and using an epitaxy process to form a compound semiconductor layer free of antiphase boundaries over the surface. The epitaxy process generally comprises disposing the semiconductor substrate in an epitaxy chamber, maintaining the substrate at a temperature between about 300° C. and about 800° C., maintaining a pressure of the epitaxy chamber between about 1 mTorr and about 600 Torr, and exposing the substrate to a gas mixture comprising a group III precursor and a group V precursor.

### BRIEF DESCRIPTION OF THE DRAWINGS

FIG. 1 is a schematic side view of a semiconductor device according to one embodiment.

FIG. 2 is a flow diagram summarizing a method according to another embodiment.

FIG. 3 is High Resolution—X-Ray Diffraction GaAs 004 peak Full-width Half Maximum data and Atomic Force Microscopy (AFM) data for GaAs layers grown on silicon with various slight misorientations.

FIG. 4 is AFM data of GaAs layer grown on 0.5° miscut and near-exact (001) Si substrates.

FIG. 5 is a High Resolution—X-Ray Diffraction omega-2theta scan around the (004) order (in the Triple Axis configuration) associated with a GaAs layer grown on a 0.3° offcut substrate with a Ge buffer layer.

FIG. 6 are AFM images of GaAs layers grown on a 0.1°, 0.3° and 0.5° offcut substrates with a Ge buffer layer.

FIG. 7 is a plot of the Anti-Phase Boundaries linear Density (APBD) measured for several samples grown on Ge-buffered offcut silicon substrates.

FIG. 8 is an AFM image showing the surface topology of a Ge Strain-Relaxed Buffer (SRB), e.g. the surface on which GaAs growth starts in some embodiments.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In this disclosure, the terms “top”, “bottom”, “side”, “above”, “below”, “up”, “down”, “upward”, “downward”, “horizontal”, “vertical”, and the like do not refer to absolute directions. Instead, these terms refer to directions relative to a basis plane of the chamber, for example a plane parallel to a substrate processing surface of the chamber.

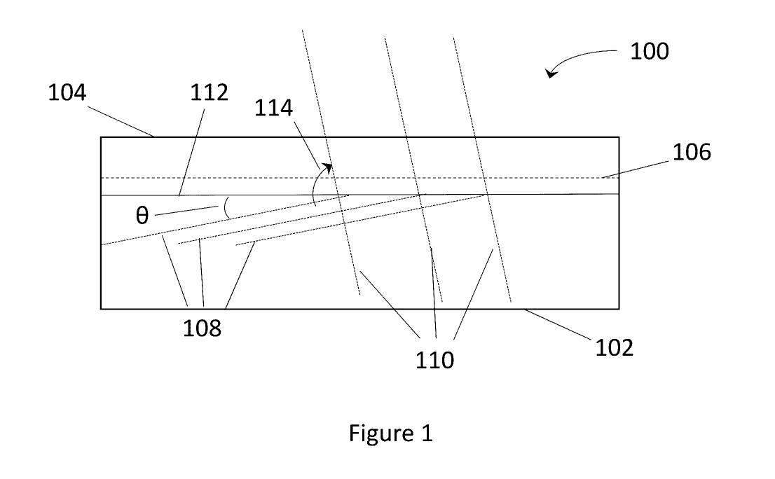

FIG. 1 is a schematic side view of a semiconductor device 100 according to one embodiment. The semiconductor device 100 comprises a semiconductor substrate 102 and a compound semiconductor layer 104 formed over the semiconductor substrate 102. Optionally, a semiconductor layer 106, for example a silicon layer, a germanium layer, or a silicon-germanium layer of any composition, may be formed between the semiconductor substrate 102 and the compound semiconductor layer 104.

The semiconductor substrate 102 has a crystal structure with a <1,0,0> plane 108 and a <1,1,0> plane 110, shown by dotted lines in FIG. 1. The semiconductor substrate 102 also has a surface 112 that forms an angle θ with respect to the <1,0,0> plane 108. The angle θ in FIG. 1 is exaggerated to simplify illustration. The angle θ is defined by sweeping a plane from the <1,0,0> orientation, such as the <1,0,0> plane 108, circularly toward the <1,1,0> direction, as demonstrated by arrow 114, for an angle of about 0.3 degrees to about 0.7 degrees. Thus, the angle θ is about 0.3 degrees to about 0.7 degrees, or about 0.5 degrees±0.2 degrees, in the <1,1,0> direction.

The surface 112 is generally known in the art as a “miscut”, suggesting an intention to cut a substrate from an ingot along the <1,0,0> plane, but with a slight error that results in a “miscut”. In this case, the semiconductor substrate 102 may be regarded as having a miscut of between about 0.3 degrees and about 0.7 degrees, or about 0.5 degrees±0.2 degrees. The semiconductor substrate may be silicon, germanium, or a mixture thereof, and/or may be coated such that the surface 112 is a layer of silicon, germanium, or a mixture thereof.

The compound semiconductor layer 104 is typically a group III/V material. The group III element in the material is generally selected from the group consisting of indium and gallium, with some optional aluminum, and the group V element in the material is generally selected from the group consisting of phosphorus, arsenic, and antimony. Mixtures of group III elements may be used, and mixtures of group V elements may be used.

The compound semiconductor layer is formed over the semiconductor surface 112, optionally on the semiconductor surface 112, by an epitaxy process to a thickness between about 200 nm and about 1,000 nm, such as between about 400 nm and about 800 nm, for example about 600 nm. The semiconductor substrate 102 is disposed in an epitaxy chamber, heated to a temperature between about 300° C. and about 800° C. under reduced pressure from about 1 mTorr to about 600 Torr, and exposed to a gas mixture containing one or more group III precursors and one or more group V precursors. The group III precursors may be group III alkyls, such as trimethylindium, trimethylgallium, or trimethylaluminum. The group V precursors may be hydrides, such as phosphine, arsine, or stibine, or alkyls such as tertiarybutylarsine, tertiarybutylphosphine, or trimethylantimony. The gas mixture may also contain an inert gas such as argon, helium, or nitrogen, and a reaction control gas such as hydrogen gas. The optional semiconductor layer 106 may be a silicon layer, a germanium layer, or a mixture of silicon and germanium, which may be formed on the surface 112 between the surface 112 and the compound semiconductor layer 104.

The inventors have discovered that a compound semiconductor layer such as the compound semiconductor layer 104, formed on a semiconductor substrate such as the substrate 102 with the surface 112, can be free of antiphase boundary defects to a thickness between about 200 nm and about 1,000 nm after thermal treatment of the substrate at a temperature between about 700° C. and about 900° C. prior to forming the compound semiconductor. Forming the same layer according to the same process using a substrate with properties different from those described with reference to the substrate 102, requires thermal treatment at temperatures of at least 950° C. to be free of antiphase boundary defects.

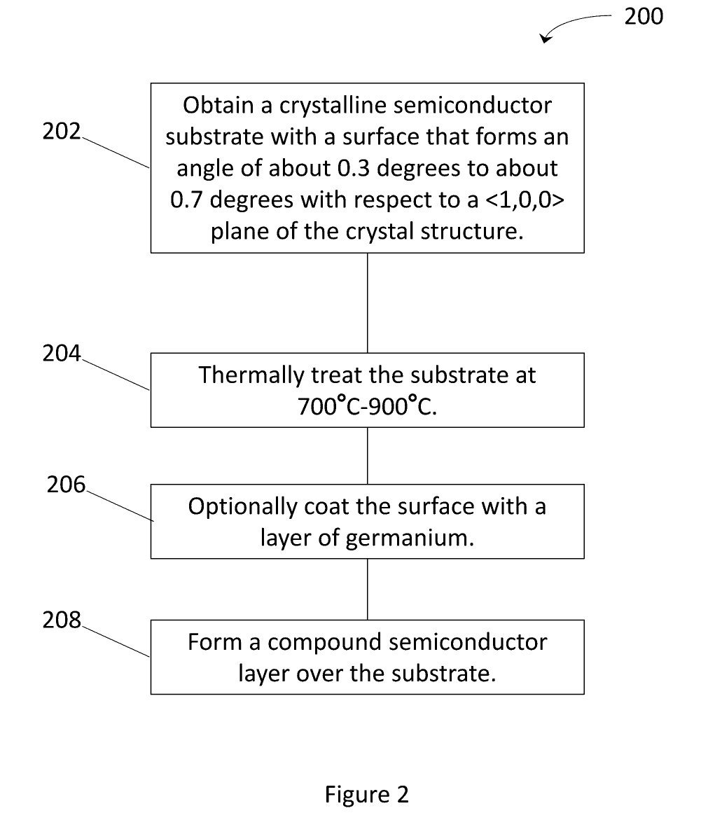

FIG. 2 is a flow diagram summarizing a method 200 according to another embodiment. At 202 a crystalline semiconductor substrate is obtained which has a surface that forms an angle of about 0.3 degrees to about 0.7 degrees with respect to a <1,0,0> plane of the crystal structure. The surface may be prepared in any desired way, for example by cleaning, such as plasma or wet cleaning, or by polishing. The substrate may be silicon, germanium, or a mixture thereof.

At 204, the substrate is thermally treated at a temperature between about 700° C. and 900° C., and at a pressure from about 1 Torr to about 600 Torr in the presence of hydrogen gas for a duration between about 1 minute and about 10 minutes. The thermal treatment promotes the formation of a favorable surface structure in the substrate silicon for growing the III-V layer with minimal density of anti-phase boundaries. The surface structure includes steps and terraces where the steps may have a height of one atomic layer to a few atomic layers. The slight miscut of the substrate between 0.3 to 0.7 degrees reduces the need for more intensive thermal treatment to achieve a favorable surface structure.

At 206, the substrate may optionally be coated with a germanium film. To form the germanium film, the substrate may be disposed in a film formation chamber, such as an epitaxy chamber or a CVD chamber, for example a group IV epitaxy chamber, and a germanium precursor, such as a germanium hydride or alkylgermanium compound, for example germane, digermane, or tertiary butylgermane, is introduced into the chamber, optionally with an inert gas such as argon, helium, or nitrogen, and optionally with hydrogen gas. The substrate is maintained at a temperature between about 400° C. and 800° C., for example about 600° C., and the chamber is maintained at a pressure of about 1 mTorr to about 100 Torr, for example about 10 Torr. Growth rate and quality of the deposited film may be adjusted by changing the temperature, pressure, and ratio of germanium precursor to other gases in the chamber, at various stages of the growth sequence from nucleation to bulk deposition.

At 208, a compound semiconductor layer is formed over the substrate, on the surface of the semiconductor substrate or optionally on the germanium layer. The substrate is disposed in a film formation chamber operable to form a compound semiconductor layer, such as a III/V layer, on the substrate. The chamber may be a molecular beam epitaxy (MBE) chamber, or an MOCVD epitaxy chamber, with multiple precursor sources and optionally different flow pathways to route the precursor sources to the chamber without mixing.

To form a III/V compound semiconductor layer, a group III precursor and a group V precursor are introduced to the chamber. Group III precursors that may be used include indium precursors and gallium precursors, optionally mixed with aluminum precursors. Exemplary group III precursors include group III alkyls such as indium alkyls (for example trimethyl indium, triethyl indium, or tritertiarybutyl indium), gallium alkyls (for example trimethyl gallium, triethyl gallium, or tri tertiary butyl gallium), and aluminum alkyls (for example trimethyl aluminum, or triethyl aluminum).

Group V precursors that may be used include phosphorus precursors, arsenic precursors, and antimony precursors. Exemplary group V precursors include group V hydrides and substituted hydrides such as phosphines and alkyl phosphines, arsines and alkyl arsines, and antimony hydrides and alkyl antimonides. Phosphine and tertiarybutyl phosphine are some exemplary phosphines that may be used. Arsine and tertiarybutyl arsine are some exemplary arsines that may be used. Stibine and trimethylantimony are some exemplary antimony sources that may be used.

The group III and group V precursors may be introduced to the chamber through different pathways to prevent pre-mixing of the precursors in the event the precursors are mutually reactive at ambient temperatures. Mixtures of group III precursors may be used, and mixtures of group V precursors may be used.

The substrate is maintained at a temperature between about 300° C. and about 800° C., such as between about 400° C. and about 600° C., for example about 500° C., and the chamber pressure is maintained from about 1 mTorr to about 100 Torr, for example about 10 Torr. The chamber pressure may be established by flowing an inert gas through the chamber prior to introducing the precursors to the chamber. The substrate temperature may be maintained by heating the substrate using a heated substrate support, which may be a resistively heated substrate support or a radiantly heated susceptor. The substrate temperature may also be maintained by direct radiant heating of the substrate in some cases.

Inert gases that may be used include argon, helium, and nitrogen. Other reaction control gases that may be used include hydrogen gas and halogen compounds such as chlorine gas, hydrogen chloride. The reaction control gases may be used to control film growth rate and quality in some cases. For example in some embodiments, higher flow rates of reaction control gases may yield lower film growth rates and higher film quality. Such reaction control gases may also improve selectivity of the film growth against dielectric surfaces in some cases.

Film formation is continued in this way until thickness of the compound semiconductor layer reaches about 200 nm to about 1,000 nm. If desired, film formation may be performed in cycles wherein a rest duration between film formation cycles allows for some intermediate thermal treatment to improve as-deposited film quality. In such rest durations, flow of the film formation group III precursors may be discontinued, while flow of group V and any inert gases may be maintained, and the substrate temperature may be set and maintained between about 700° C. and about 800° C. for a duration of about 10 sec to about 10 min. After the rest duration, temperature of the substrate may be returned to the target temperature for film formation, and the film formation precursors re-introduced to the chamber.

The inventors have obtained antiphase boundary (APB) free—GaAs epilayers on (quasi) nominal 001) silicon substrates using methods described herein. As Si substrates always have a small random offcut angle from their nominal surface plane, such substrates may be referred to as “quasi-nominal”. It has been found that a small offcut angle as described herein has a significant effect on the GaAs epilayer properties, including a large effect on density of APBs. The methods described herein were able to obtain on 0.5° offcut substrates GaAs epilayers that were single domain (e.g. without any APB) and smooth (˜1 nm root mean square roughness for 5×5 μm² atomic force microscopy images). Such APB-free GaAs epifilms obtained on silicon with such a small miscut angle (0.5° instead of the 4° to 6° typically found in the literature) are even more compatible with the existing silicon manufacturing technology that uses “quasi-nominal” substrates. A germanium thick strain-relaxed buffer was inserted in other cases between the GaAs layer and the silicon substrate underneath in order to accommodate the 4% lattice mismatch between the two.

The semiconductor devices and methods disclosed herein may be made and practiced using a metal organic CVD epitaxy chamber available from Applied Materials, Inc., of Santa Clara, Calif. It is expected that chambers available from other manufacturers may also be used to make and practice the devices and methods disclosed herein. In the following three example test cases, Trimethylgallium (TMGa) and tertiarybutylarsine (TBAs) organometallic precursors were used as Ga and As sources, respectively. Ultra-pure hydrogen was used as the carrier gas. Deposition occurred between 500° C.-700° C. and 20 torr-100 torr on 775 μm thick 300 mm silicon substrates with <0,0,1> orientation with a miscut.

Table 1 shows the result of growing GaAs layers on 300 mm silicon substrates having the indicated offcut angles. Each of the four substrates was sequentially processed in an Applied Materials cluster tool that includes the MOCVD epi chamber and an industrial dry clean Siconi™ native oxide removal chamber. Following native oxide removal, each substrate received a <5 minute<900 C thermal anneal immediately prior to 400 nm GaAs deposition using conditions as described herein. High Resolution X-Ray Diffraction (XRD) measurements were performed to evaluate the GaAs crystallinity at three locations on each substrate.

TABLE 1
GaAs Grown on Offcut Silicon

| | Offcut | XRD FWHM | RMS (nm) | APBD |
|---|---|---|---|---|
| Sample # | Angle | (Arcsec) | 5 μm × 5 μm | (μm⁻¹) |
| 1 | 0.1 | 800/769/813 | 4.15 | 2.6 |
| 2 | 0.1 | 807/809/827 | 2.30 | 2.5 |
| 3 | 0.05 | 831/824/834 | 4.33 | 3.8 |
| 4 | 0.3 | 746/760/754 | 0.964 | 0 |

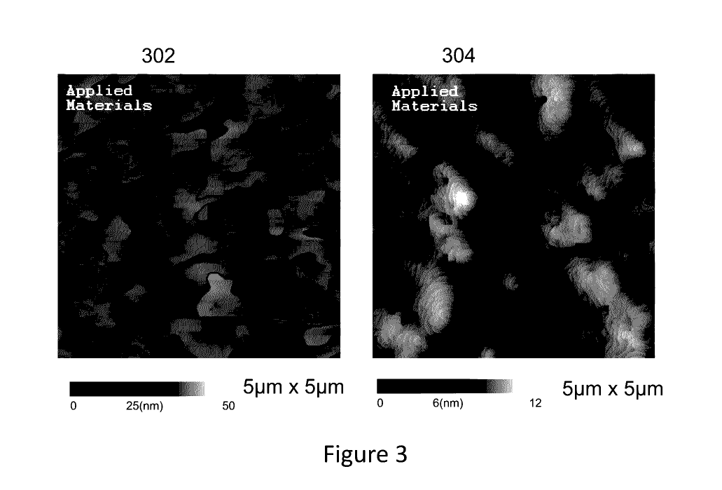

The GaAs grown on 0.3° misoriented Si showed the narrowest XRD 004 GaAs peak (FWHM “full width half maximum” column of FIG. 3) at all three locations on the substrate, suggesting the best quality. Atomic Force Microscopy (AFM) was used to probe the surface topography in a 5×5 μm² region of the resulting GaAs layers in terms of the APB features and roughness. GaAs layers on the three Si substrates having miscuts 0.1° or lower showed antiphase boundaries, illustrated by the distinct dark lines marking defined regions on the AFM image at 302. The density of the APB's, listed in Table 1 (APBD column), are >2 um⁻¹ for these three GaAs layers, causing higher overall Root Mean Square roughness (RMS column in Table 1) for these layers, when compared to the GaAs grown on the 0.3° miscut Si wafer (sample 4) which showed only nanometer high step-edge features and had no observable APB's from its AFM image at 304.

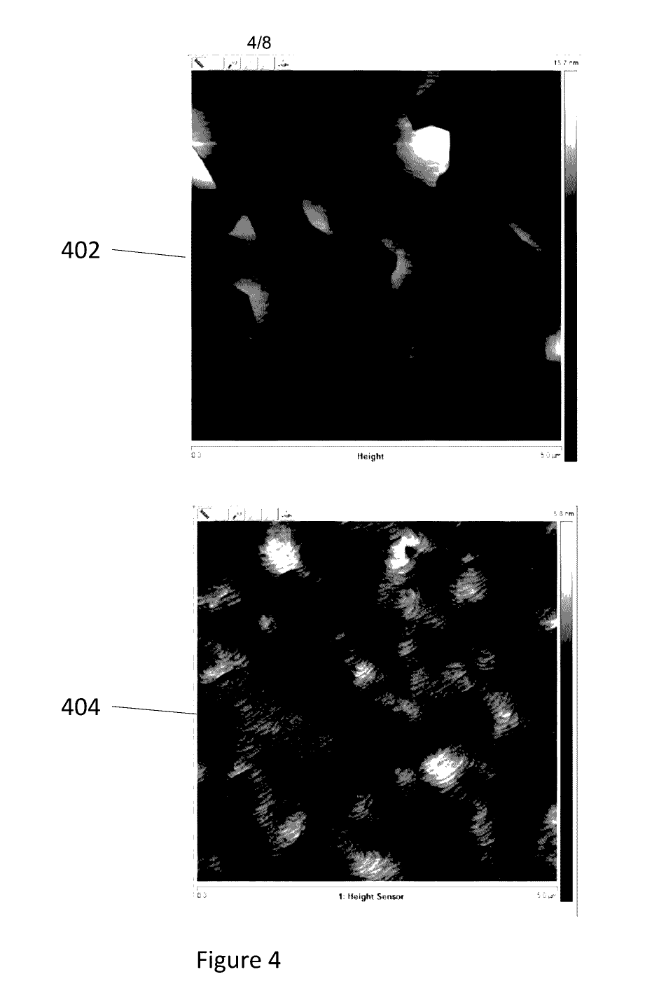

An equivalent test was performed using an identical Applied Materials cluster tool located at another facility. FIG. 4 shows two AFM images 402 and 404 of 400 nm GaAs layers on almost exact (001) Si wafer and one with a 0.5° miscut. Growth conditions were as described herein. No anti-phase boundary features are visible in the image 404 of the GaAs grown over the 0.5° miscut sample, and the layer is very smooth (0.8 nm RMS roughness) with only steps less than a nanometer high running contiguously across. In contrast, the image 402 of the GaAs grown on the almost exactly oriented sample again showed the distinct dark APB lines that break the surface into regions separated by deep crevices for an overall rougher morphology (1.4 nm RMS roughness).

In the third example case, silicon substrates from Sun Edison were obtained with intentional miscuts from <0,0,1> of 0.1°, 0.3° or 0.5°, in order to study the effect of small miscut angles. Prior to III-V epitaxy, a typically one micron thick Ge Strained Relaxed Buffer (SRB) was grown in a separate group IV epitaxy tool. The threading dislocation density in those Ge SRBs was typically around 10⁷ cm⁻². Prior to GaAs epitaxy, a wet cleaning of the Ge surface was performed based on ozone in order to refresh the Ge surface. Then, a Siconi™ surface treatment in an Applied Materials cluster tool was also used to remove the remaining oxides on the Ge surface. The substrates remained under vacuum in the cluster tool where they were then transferred into the 300 mm MOCVD chamber for GaAs epitaxy. Growth conditions were as described herein. Again, High Resolution X-ray Diffraction (HR-XRD) and Atomic Force Microscopy were employed to characterize the grown layers.

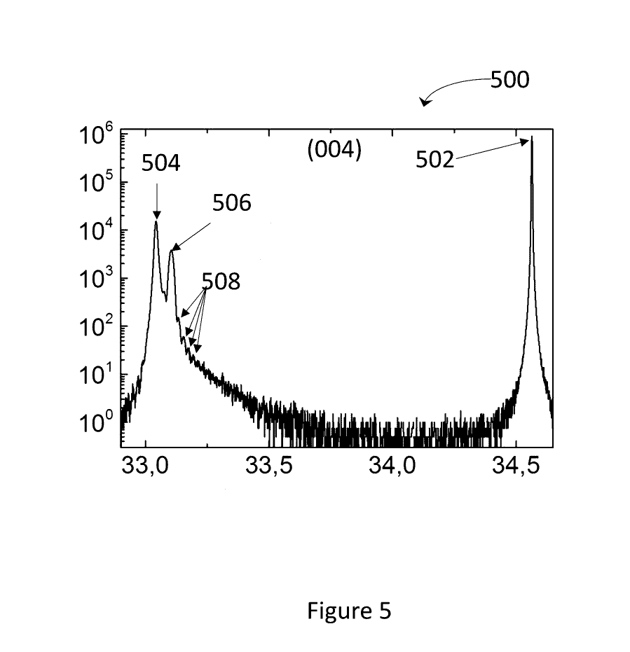

FIG. 5 is a HR-XRD omega-2theta scan 500 around the (004) order (in the Triple Axis configuration) associated with the GaAs layer grown on the 0.3° miscut substrates, as described above. This corresponds to GaAs layers with a 0.3 μm⁻¹ APB linear density. Intensity, in hits per second, is along the vertical axis, and Omega-2Theta, in degrees, is along the horizontal axis. Three peaks are visible on the XRD profile. The most intense peak 502, at a 34.56° incidence angle, is originating from the silicon substrate. The next most intense peak 504, at slightly more than 33°, corresponds to the germanium SRB. Finally, the third peak 506, at around 33.1°, is due to the GaAs top layer. The thick GaAs and Ge layers are thus single crystal as diffraction peaks are intense and sharp. Thickness interference fringes 508 can be observed as well on both sides of the GaAs layer peak. This indicates that the GaAs layer is smooth and of high crystalline quality.

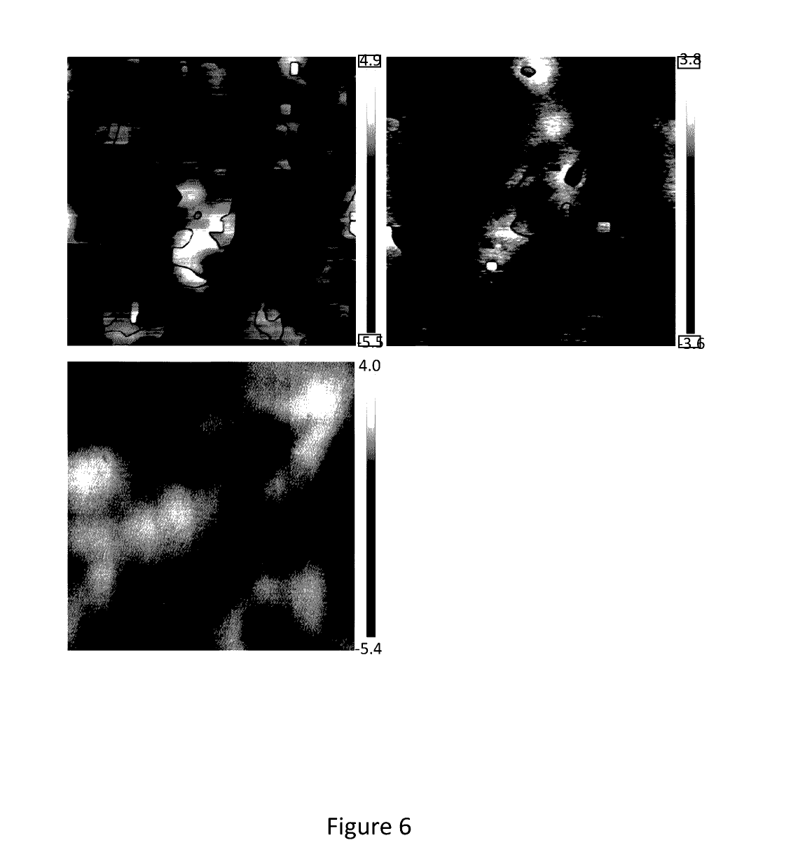

FIG. 6 shows AFM images of the GaAs layers on the above Si substrates with Ge buffer layers. The AFM images show surface morphology of a 5×5 μm² region of the GaAs epilayers. The only difference among the samples is the offcut of the Si substrate used for growth. Image (a) shows a comparative example corresponding to an epitaxial growth on a Si substrate with a 0.1° miscut. Image (b) corresponds to a growth on a substrate with a 0.3° miscut. Finally, image (c) corresponds to growth on a substrate with a 0.5° miscut. Antiphase boundaries (APBs) appear as darker lines on those images. The APB linear density was obtained by (i) measuring the total APB length in a given area, and (ii) dividing the resulting length by the area. It is therefore expressed in μm/μm², e.g. in μm⁻¹. The linear density is 2.8 μm⁻¹ for the GaAs grown on a 0.1° miscut silicon substrate. It goes down to 0.3 μm⁻¹ when growing on a 0.3° miscut substrate. Finally, we have a single domain GaAs film on a 0.5° miscut substrate, with therefore no anti-phase boundaries anymore. The APB linear density is null in that case.

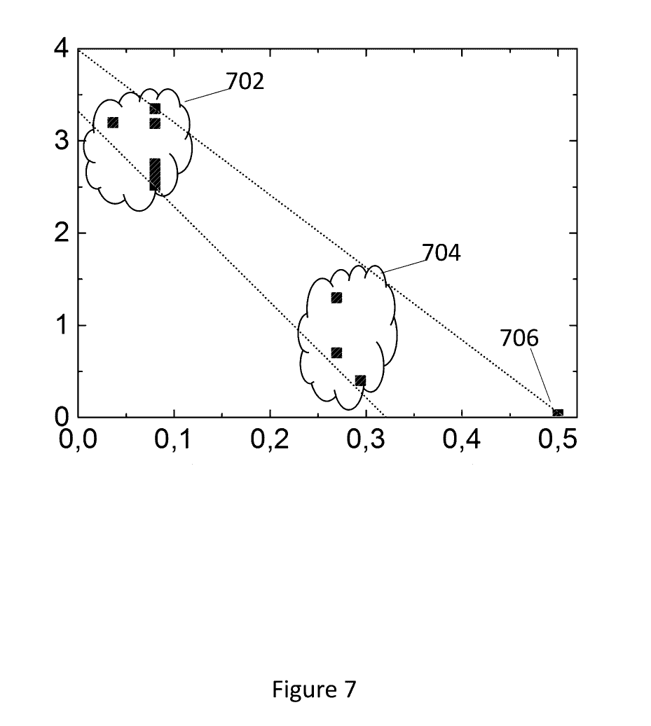

FIG. 7 is a plot of the APB linear Density in μm⁻¹ (APBD, vertical axis) measured for several samples grown on Ge-buffered offcut silicon substrates with different miscut angles (degrees, horizontal axis): 0.1°, 0.3° and 0.5°, wherein the samples using a 0.1° angle, at 702, are comparative examples. For growths performed on 0.1° or less miscut substrates, the antiphase boundary linear density is always higher than one per micrometer. All such comparative examples grown by the inventors have exhibited linear APB density (with sometimes slight growth condition variations) in between 2.5 and 3.5 μm⁻¹. The three GaAs layers grown on substrates with a 0.3° offcut angle, at 704, have a linear density of APB in between 0.3 and 1.4 μm⁻¹. Finally, if the same GaAs layers are grown on 0.5° miscut Si substrates, we then obtain single domain GaAs epilayers even for slight variations in the epitaxial growth sequence, as for the samples at 706. Thus similar trends apply for GaAs grown on Ge-buffered Si as those directly on Si.

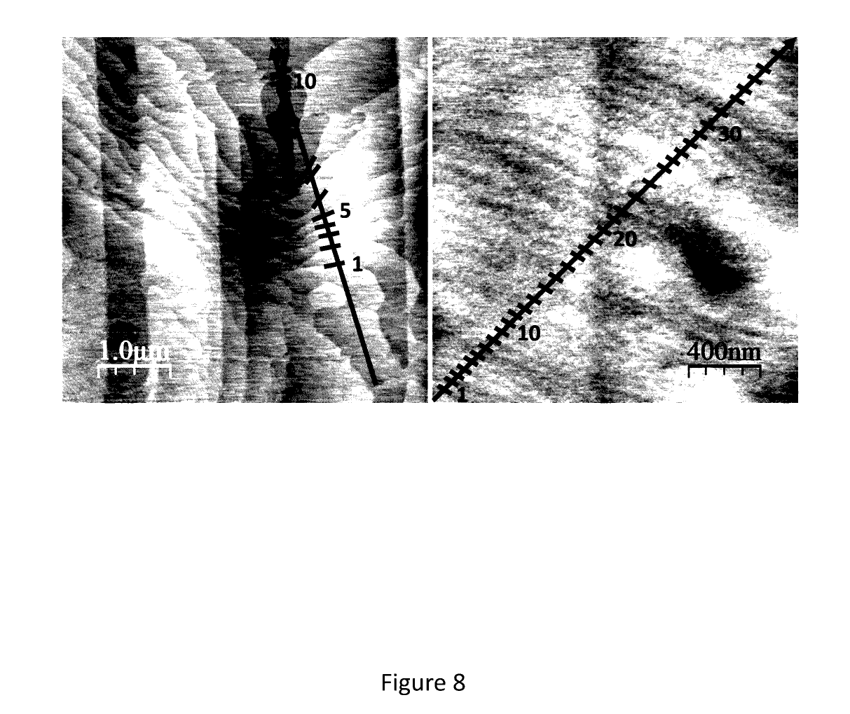

FIG. 8 is an AFM image showing the surface topology of the Ge SRB, e.g. the surface on which GaAs growth starts in some embodiments. The images of FIG. 8 clearly show that the miscut angle of the starting silicon substrate influences the density of terraces as expected. The spatial scale of the two images is not the same, and was chosen in order to display a similar amount of terraces. The left image shows 11 terraces over 5 μm, with an average terrace length of around 450 nm. In that case, the miscut of the substrate (from X Ray Diffraction) was only 0.04°. With such a miscut angle, one would expect a spacing between bi-atomic steps of 405 nm (=a_{Ge}/(2*tan(0.04°, with a_{Ge}=5.658 Å), which is close to the value experimentally obtained. The right image shows 36 terraces over 2.8 μm, translating into an average terrace length of 78 nm. In that case, the miscut of the substrate was 0.28° (once again from X Ray Diffraction). With such a miscut angle, one would expect a terrace length of 58 nm)))(=a_{Ge}/(2*tan(0.28° for bi-atomic steps, again similar to the experimental value. Growing GaAs on such a surface is therefore advantageous. Moreover, we undeniably have bi-atomic steps between terraces rather than mono-atomic steps, even for such small miscut angles)(<0.5°.

It has been found that (i) small miscut variations greatly influence how GaAs grows either directly on silicon substrates or with Ge buffer layer on the Si substrate, and (ii) the miscut angle that yields single domain layers in MOCVD is as low as 0.3° The methods described herein, optionally using an intermediate Ge layer, eliminates high temperature Si preparation at temperatures of 950° C. or higher and enables blanket APB-free GaAs epifilms on lattice-mismatched silicon.

While the foregoing is directed to certain embodiments, other and further embodiments may be devised without departing from the basic scope of this disclosure.

What is claimed is:

1. A semiconductor device, comprising
a semiconductor substrate having a crystal structure with a <1,0,0> plane and a <1,1,0> plane and a surface that forms an angle of about 0.3 degrees to about 0.7 degrees with the <1,0,0> plane in the direction of the <1,1,0> plane; and
a compound semiconductor layer formed over the surface.

2. The semiconductor device of claim 1, wherein the compound semiconductor layer comprises a first element from the group consisting of indium and gallium and a second element from the group consisting of phosphorus, arsenic, and antimony.

3. The semiconductor device of claim 1, wherein the compound semiconductor layer is free of antiphase boundary defects.

4. The semiconductor device of claim 2, wherein the compound semiconductor layer is free of antiphase boundary defects.

5. The semiconductor device of claim 3, wherein the compound semiconductor layer has a thickness between about 200 nm and about 1,000 nm.

6. The semiconductor device of claim 4, wherein the compound semiconductor layer has a thickness between about 200 nm and about 1,000 nm.

7. The semiconductor device of claim 1, wherein the semiconductor substrate is silicon, germanium, or a mixture thereof.

8. The semiconductor device of claim 1, further comprising a germanium layer formed between the surface and the compound semiconductor layer.

9. The semiconductor device of claim 2, further comprising a third element from the group consisting of indium, gallium, and aluminum, wherein the third element is different from the first element.

10. A method of forming a semiconductor device, comprising:
forming a surface on a semiconductor substrate having a crystal structure with a <1,0,0> plane and a <1,1,0> plane, the surface forming an angle of about 0.3 degrees to about 0.7 degrees with the <1,0,0> plane in the direction of the <1,1,0> plane; and
using an epitaxy process to form a compound semiconductor layer free of antiphase boundaries over the surface.

11. The method of claim 10, further comprising thermally treating the substrate at a temperature between about 700° C. and about 900° C. prior to the epitaxy process.

12. The method of claim 10, wherein the compound semiconductor layer is formed with a thickness between about 200 nm and about 1,000 nm.

13. The method of claim 10, wherein the epitaxy process comprises disposing the semiconductor substrate in an epitaxy chamber, heating the substrate to a temperature between about 300° C. and about 800° C., maintaining a pressure in the epitaxy chamber between about 1 mTorr and about 600 Torr and exposing the substrate to a gas mixture comprising a group III precursor and a group V precursor.

14. The method of claim 13, further comprising using an epitaxy process to form a group IV semiconductor layer on the semiconductor substrate prior to forming the compound semiconductor layer.

15. The method of claim 13, wherein the group III precursor includes a first element from the group consisting of indium and gallium and a second element from the group consisting of phosphorus, arsenic, and antimony.
